(19) United States
(12) Patent Application Publication
(10) Pub. No.: US 2002/0090468 A1
(43) Pub. Date: Jul. 11, 2002

(54) Method of manufacturing carbon nanotube

(75) Inventors: Hajime Goto, Wako-shi (JP); Terumi Furuta, Wako-shi (JP); Toshio Tokune, Wako-shi (JP); Yoshiya Fujiwara, Wako-shi (JP); Toshiyuki Ohashi, Wako-shi (JP)

Correspondence Address: ARENT FOX KINTNER PLOTKIN & KAHN, 1050 CONNECTICUT AVENUE, N.W., SUITE 600, WASHINGTON, DC, 20036, US

(73) Assignee: HONDA GIKEN KOGYO KABUSHIKI KAISHA

(21) Appl. No.: 09/984,581

(22) Filed: Oct. 30, 2001

(30) Foreign Application Priority Data
Oct. 30, 2000 (JP) 2000-329997
Sep. 13, 2001 (JP) 2001-277722

(51) Int. Cl. C23C 16/00; H05H 1/48

(52) U.S. Cl. 427/580; 427/249.1; 427/249.2

(57) ABSTRACT

There is provided a method of manufacturing a carbon nanotube so as to be able to increase the yield of a web and to increase the amount of a carbon nanotube contained in the web. A high-energy heat source is caused to act on carbon in the presence of catalysts. The catalysts include a main catalyst made of at least one metal which is selected from the group consisting of an iron group element, a platinum group element, and a rare earth element, and an auxiliary catalyst made of a material which causes an exothermic reaction in a process of generating the web including the carbon nanotube. The auxiliary catalyst is made of a material for generating a carbide more stable in terms of thermal energy than a carbide generated by the main catalyst. The free formation energy of the carbide generated from the material is smaller than the free formation energy of the carbide generated by the main catalyst. The main catalyst is made of at least one metal which is selected from the group consisting of Fe, Co, Ni, Rh, Ru, Pd, Pt, Y, La, and Ce. The auxiliary catalyst is made of at least one material selected from the group consisting of Ti, Zr, Hf, V, Nb, Ta, Cr, Mo, W, B, Al, and Si. Typically the main catalyst is made of Ni—Y, and the auxiliary catalyst is made of Ti.

### BACKGROUND OF THE INVENTION

1. Field of the Invention

The present invention relates to a method of manufacturing a carbon nanotube.

2. Description of the Related Art

Heretofore, it is known in the art that a web as an intermediate product including a carbon nanotube is produced by causing a metal catalyst to act on a carbon vapor in a high temperature atmosphere. The web usually includes a carbon nanotube, which is desired to be obtained, amorphous carbon, and a residual catalyst. The web is subsequently highly purified to obtain the carbon nanotube.

If a sufficiently high temperature is not achieved when the metal catalyst acts on the carbon vapor, the amount of amorphous carbon, which is considered to be an impurity, is increased. Therefore, a laser, a plasma, an arc discharge, or the like is used as a high-energy heat source for producing the high temperature atmosphere.

The metal catalyst is made of iron (Fe), cobalt (Co), and nickel (Ni), which are iron-group elements, either singly or in combination with each other. It is known in the art that the metal catalyst is made of rhodium (Rh), ruthenium (Ru), palladium (Pd), and platinum (Pt), which are platinum-group elements, either singly or in combination with each other. It is also known in the art that the metal catalyst is made of yttrium (Y), lanthanum (La), cerium (Ce), which are rare-earth-group elements, either singly or in combination with Fe, Co, and Ni, which are iron-group elements. It is recognized in the art that if an arc discharge is used as the high-energy heat source, then the yield of the web is increased when a mixed catalyst of nickel and yttrium (Ni—Y) is used.

However, even when the (Ni—Y) mixed catalyst is used, the web contains about 40% of amorphous carbon, about 20% of residual catalyst, and only about 40% of carbon nanotube which is to be obtained.

### SUMMARY OF THE INVENTION

It is therefore an object of the present invention to provide a method of manufacturing a carbon nanotube so as to be able to increase the yield of a web as an intermediate product including such a carbon nanotube.

Another object of the present invention to provide a method of manufacturing a carbon nanotube so as to be able to increase the amount of carbon nanotube contained in such a web.

To achieve the above object, there is provided in accordance with the present invention a method of manufacturing a carbon nanotube, comprising the step of generating a web including a carbon nanotube by causing a high-energy heat source to act on carbon in the presence of catalysts, the catalysts including a main catalyst made of at least one metal which is selected from the group consisting of an iron group element, a platinum group element, and a rare earth element, is substantially a pure material or an alloy, and may contain unavoidable impurities, and an auxiliary catalyst made of a material which causes an exothermic reaction in a process of generating the web including the carbon nanotube.

With the above method of manufacturing a carbon nanotube, when the high-energy heat source is caused to act on carbon in the presence of the catalysts, the auxiliary catalyst causes an exothermic reaction at first. The exothermic reaction increases the temperature in the vicinity of the carbon and the catalysts. Therefore, the vaporization of the carbon and the main catalyst is promoted, increasing the yield of a web as an intermediate product including a carbon nanotube.

The vaporization of the carbon and the main catalyst is promoted, generating a large amount of vapor of the carbon and the main catalyst in a limited region. Consequently, the carbon and the main catalyst are uniformly mixed with each other in a gaseous phase. Consequently, the amount of the carbon nanotube contained in the web is increased.

The auxiliary catalyst may be made of such a material that it causes the exothermic reaction by generating a carbide, for example. The generation of the carbide results in a competitive reaction between the auxiliary catalyst and the main catalyst for producing the carbon nanotube. In the exothermic reaction, the carbide should preferably be generated solely by the auxiliary catalyst.

In the method according to the present invention, the auxiliary catalyst should preferably be made of a material which is more reactive than the main catalyst in the exothermic reaction in the process of generating the web including the carbon nanotube. Stated otherwise, the auxiliary catalyst should preferably be made of a material for generating a carbide more stable in terms of thermal energy than a carbide generated by the main catalyst.

The auxiliary catalyst should preferably be made of such a material that the free formation energy of the carbide generated therefrom is smaller than the free formation energy of the carbide generated by the main catalyst. As a result, the auxiliary catalyst can generate a carbide more stable in terms of thermal energy than a carbide generated by the main catalyst.

The main catalyst may be made of at least one metal which is selected from the group consisting of Fe, Co, Ni, Rh, Ru, Pd, Pt, Y, La, and Ce. Fe, Co, and Ni are iron-group elements, Rh, Ru, Pd, and Pt are platinum-group elements, and Y, La, and Ce are rare-earth-group elements.

The auxiliary catalyst may be made of at least one material selected from the group consisting of titanium (Ti), zirconium (Zr), hafnium (Hf), vanadium (V), niobium (Nb), tantalum (Ta), chromium (Cr), molybdenum (Mo), tungsten (W), boron (B), aluminum (Al), and silicon (Si). Ti, Zr, and Hf are IVA-group elements, V, Nb, and Ta are VA-group elements, Cr, Mo, and W are VIA group elements, B and Al are IIIB-group elements, and Si is a IVB-group element.

For example, the main catalyst is made of a mixture of Ni and Y, each of which is substantially a pure material or an alloy and may contain unavoidable impurities, and the auxiliary catalyst is made of at least one material selected from the group consisting of Ti, Zr, Hf, Nb, B, and Si, is substantially a pure material or an alloy, and may contain unavoidable impurities. Specifically, the main catalyst may be made of a mixture of Ni and Y, and the auxiliary catalyst may be made of Ti.

The main catalyst may be made of a mixture of Ni and Fe, and the auxiliary catalyst may be made of Ti. Alternatively, the main catalyst may be made of Co, and the auxiliary catalyst may be made of one of Ti and Cr. Further alternatively, the main catalyst may be made of at least one material which is selected from the group consisting of Ni, La, and Rh, is substantially a pure material or an alloy, and may contain unavoidable impurities, and the auxiliary catalyst may be made of Ti, which is substantially a pure material and may contain unavoidable impurities.

Each of the materials for use as the main and auxiliary catalysts may be substantially a pure material or an alloy and may contain unavoidable impurities.

The carbon should preferably serve as carbon electrodes, and the high-energy heat source should preferably comprise an arc discharge caused between the carbon electrodes. With the high-energy heat source being an arc discharge caused between the carbon electrodes, the yield of the web can be increased using the catalysts.

Preferably, the carbon electrodes contain a total amount of the main and auxiliary catalysts which is in the range from 10 to 35 weight % with respect to the total amount of the carbon electrodes. If the total amount of the main and auxiliary catalysts were less than 10 weight % of the overall carbon electrode, then no sufficient amount of carbon nanotube would be produced. If the total amount of the main and auxiliary catalysts were more than 35 weight % of the overall carbon electrode, then no further advantageous effects are achieved.

Preferably, the auxiliary catalyst is mixed in an amount in excess of 0.1 atomic % of the total amount of the main and auxiliary catalysts. If the amount of the auxiliary catalyst were equal to or less than 0.1 atomic % of the total amount of the main and auxiliary catalysts, then no sufficient heat of formation would be obtained.

The above and other objects, features, and advantages of the present invention will become apparent from the following description when taken in conjunction with the accompanying drawings which illustrate a preferred embodiment of the present invention by way of example.

### BRIEF DESCRIPTION OF THE DRAWINGS

FIG. 1 is a schematic view of an arc discharging system for use in a method of manufacturing a carbon nanotube according to the present invention;

FIG. 2 is a cross-sectional view of a graphite electrode for use in the method of manufacturing a carbon nanotube according to the present invention; and

FIG. 3 is a graph showing the relationship between the free formation energy and temperature of carbides generated by a main catalyst and carbides generated by an auxiliary catalyst.

### DETAILED DESCRIPTION OF THE PREFERRED EMBODIMENT

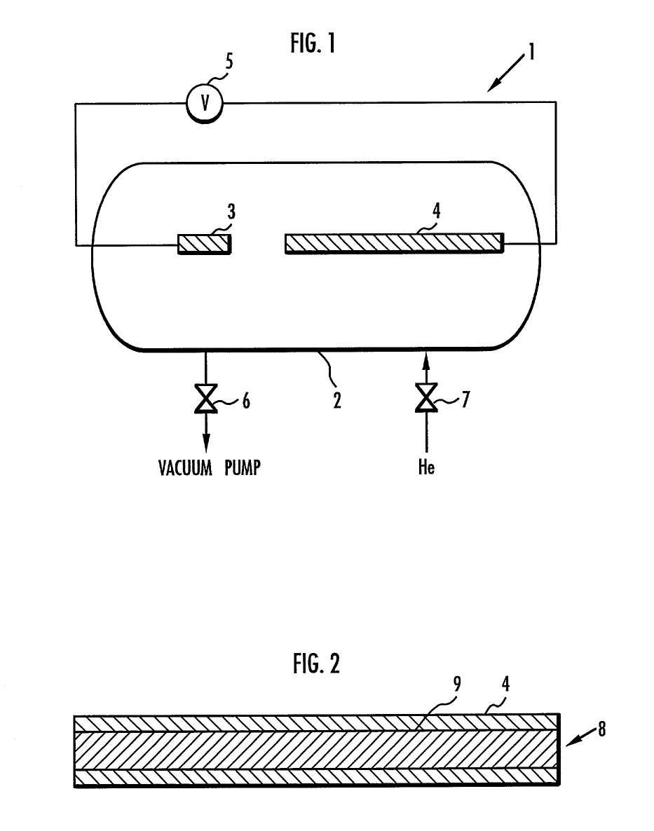

A method of manufacturing a carbon nanotube according to the present invention employs an arc discharging system 1 shown in FIG. 1. The arc discharging system 1 has a negative electrode 3 fixedly mounted in an arc discharging chamber 2 that can be opened and closed and a positive electrode (consumable electrode) 4 mounted in the arc discharging chamber 2 for movement toward and away from the negative electrode 3. The negative electrode 3 and the positive electrode 4 are connected to a power supply 5. The arc discharging chamber 2 is connected to a vacuum pump (not shown) via an on/off valve 6 and also connected to a helium gas source (not shown) via an on/off valve 7.

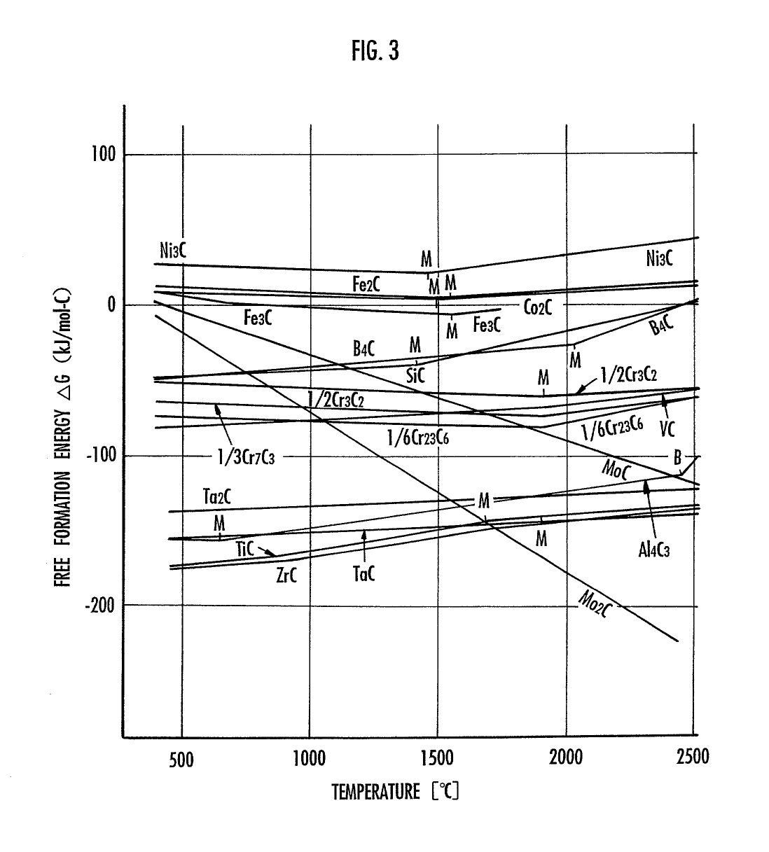

The negative electrode 3 comprises a graphite electrode in the shape of a solid cylindrical body. As shown in FIG. 2, the positive electrode 4 comprises a graphite electrode in the shape of a hollow cylindrical body having an axial hollow space 8 defined therein. The axial hollow space 8 is filled with a mixed catalyst 9 which comprises a main catalyst and an auxiliary catalyst that are mixed with a graphite powder.

The main catalyst may be made of at least one metal selected from the group consisting of Fe, Co, Ni, Rh, Ru, Pd, Pt, Y, La, and Ce. For example, the main catalyst is a (N—Y) mixed catalyst of Ni and Y which are mixed with each other at a molecular ratio of 1:1. Each of the above metals may be a substantially pure material which may contain unavoidable impurities.

The auxiliary catalyst may be made of a material which causes an exothermic reaction with the carbon of the electrodes when an arc discharge is carried out between the negative electrode 3 and the positive electrode 4 in the arc discharging chamber 2. The material which causes the exothermic reaction should preferably be more liable to react than the main catalyst in the exothermic reaction. The material which is more liable to react than the main catalyst in the exothermic reaction should preferably produce carbides more stable in terms of thermal energy than carbides generated by the main catalyst.

In order for the material of the auxiliary catalyst to produce carbides which are stable in terms of thermal energy, the free formation energy (AG) of the carbides needs to be smaller than free formation energy of the carbides generated by the main catalyst. The auxiliary catalyst may be made of at least one material selected from the group consisting of Ti, Zr, Hf, V, Nb, Ta, Cr, Mo, W, B, Al, and Si. For example, the auxiliary catalyst is made of Ti alone. Each of the above materials may be a substantially pure material which may contain unavoidable impurities.

The relationship between the free formation energy of the carbides generated by the main catalyst, the free formation energy of the carbides generated by the auxiliary catalysts, and temperature is shown in FIG. 3. It is clear from FIG. 3 that the free formation energy of the carbides of Ti, Zr, V, Ta, Cr, Mo, B, Al, and Si of the auxiliary catalyst is smaller than the free formation energy of the carbides of Fe, Co, Ni of the main catalyst in a temperature range from 500 to 2500° C.

In the mixed catalyst 9 shown in FIG. 2, the total amount of the main and auxiliary catalysts is in the range of 10 to 35 weight % of the overall graphite electrode as the positive electrode 4. If the total amount of the main and auxiliary catalysts were less than 10 weight % of the overall graphite electrode, then no sufficient amount of carbon nanotube would be produced. If the total amount of the main and auxiliary catalysts were more than 35 weight % of the overall graphite electrode, then no further advantageous effects are achieved.

The auxiliary catalyst should preferably be mixed in an amount in excess of 0.1 atomic % of the total amount of the main and auxiliary catalysts. If the amount of the auxiliary catalyst were equal to or less than 0.1 atomic % of the total amount of the main and auxiliary catalysts, then no sufficient heat of formation would be obtained.

The method of manufacturing a carbon nanotube with the arc discharging system 1 shown in FIG. 1 will be described below. First, a graphite electrode in the shape of a solid cylindrical body is installed as the negative electrode 3 in the arc discharging chamber 2. Then, a graphite electrode whose hollow space 8 is filled with the mixed catalyst 9 of the main and auxiliary catalysts is installed as the positive electrode 4 in the arc discharging chamber 2. Thereafter, the arc discharging chamber 2 is closed. Then, the on/off valve 6 is opened to evacuate the arc discharging chamber 2. The on/off valve 6 is closed and the on/off valve 7 is opened to introduce a helium gas into the arc discharging chamber 2. As a result, the atmosphere in the arc discharging chamber 2 is replaced with a highly pure helium atmosphere under the pressure ranging from 0.01 to 0.2 MPa, e.g., the pressure of 0.06 MPa.

Then, a control device (not shown) automatically feeds the positive electrode 4 toward the negative electrode 3. At the same time, the power supply 5 is voltage-feedback-controlled to apply a constant voltage of 35 V and supply a constant current of 100 A between the negative electrode 3 and the positive electrode 4, generating an arc discharge between the negative electrode 3 and the positive electrode 4.

When the arc discharge is generated, chiefly the auxiliary catalyst of the catalysts contained in the positive electrode 4 causes an exothermic reaction with the carbon of the electrodes to generate carbides. At this time, the tip end of the positive electrode 4 is heated by the arc discharge. As the auxiliary catalyst causes the exothermic reaction, a free edge area toward the negative electrode of the positive electrode 4 is heated.

As a result, the vaporization of the carbon and the main catalyst is promoted, generating a large amount of vapor of the carbon and the main catalyst in a limited region which is heated by the arc discharge. Consequently, the carbon and the main catalyst are uniformly mixed with each other in a gaseous phase, producing a large amount of webs including carbon nanotubes. The webs are either attached to the inner wall of the arc discharging chamber 2 or deposited on the bottom of the arc discharging chamber 2.

In the method of manufacturing a carbon nanotube according to the present invention, since a large amount of vapor of the carbon and the main catalyst is generated in the limited region, the yield of the webs is increased. Furthermore, the webs which are either attached to the inner wall of the arc discharging chamber 2 or deposited on the bottom of the arc discharging chamber 2 contain many webs shaped like spider webs, which contain a large amount of carbon nanotubes.

The carbon nanotubes can be extracted when the webs removed from the arc discharging chamber 2 are highly purified after the arc discharge.

Inventive and Comparative Examples will be described below.

Inventive Example 1:

First, a hollow cylindrical, highly pure graphite rod having an outside diameter of 6 mm, an inside diameter of 3 mm, and a length of 150 mm was prepared. Then, the hollow space in the graphite rod was filled with a mixed catalyst which has been mixed in advance, producing the positive electrode 4 shown in FIG. 1. The mixed catalyst was a mixture of powders of Ni and Y as the main catalyst, a powder of Ti as the auxiliary catalyst, and a powder of graphite. The mixed catalyst was prepared to mix the constituents at ratios of Ni:Y:Ti:C=2:2:2:94 (atom number ratios) with respect to the total amount of the positive electrode. The total weight (initial weight) of the positive electrode 4 was 7.8 g.

Then, the negative electrode 3 in the form of a solid cylindrical, highly pure graphite rod and the positive electrode 4 were installed in the arc discharging system 1 shown in FIG. 1, and then the arc discharging chamber 2 was closed. The on/off valve 6 was opened to evacuate the arc discharging chamber 2, and thereafter the on/off valve 6 was closed and the on/off valve 7 was opened to introduce a helium gas into the arc discharging chamber 2. The atmosphere in the arc discharging chamber 2 was replaced with a highly pure helium atmosphere under the pressure of 0.06 MPa.

Then, a control device (not shown) automatically fed the positive electrode 4 toward the negative electrode 3. At the same time, the power supply 5 was feedback-controlled in voltage to apply a constant voltage of 35 V and supply a constant current of 100 A between the negative electrode 3 and the positive electrode 4, generating an arc discharge between the negative electrode 3 and the positive electrode 4 thereby to manufacture carbon nanotubes.

As a result, the positive electrode 4 was consumed, generating webs containing carbon nanotubes. The generated webs were attached to the inner wall of the arc discharging chamber 2 or deposited on the bottom of the arc discharging chamber 2.

Then, the webs were retrieved as a web (web A) shaped like a spider web and a web (web B), other than the web shaped like a spider web, attached to the inner wall of the arc discharging chamber 2. The retrieved webs were weighed. The web A had a weight of 1.0 g, and the web B had a weight of 1.5 g. The total yield amount of the retrieved webs was therefore 2.5 g. The weight of the positive electrode 4 was measured, and the consumed amount of the positive electrode 4 from the initial weight thereof was calculated. The total yield percentage of the webs was also calculated. The consumed amount of the positive electrode 4 was 7.3 g, and the total yield percentage of the webs was 34.2%.

In order to estimate the content of the carbon nanotubes in the web A, a G/D (ordered structure component/disordered structure component) ratio of the web A was measured according to Raman spectroscopy. The carbon nanotube corresponds to the ordered structure component. In this example, the G/D ratio of the web A was 5.13.

The consumed amount of the positive electrode 4, the total yield amount of the retrieved webs, the total yield percentage of the retrieved webs, and the G/D ratio are shown in Table 1.

Inventive Example 2:

Carbon nanotubes were manufactured in the same manner as with Inventive Example 1 except that Ti was replaced with Zr as the auxiliary catalyst and the constituents were mixed at ratios of Ni:Y:Zr:C=2:2:1:95 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 1.

Inventive Example 3:

Carbon nanotubes were manufactured in the same manner as with Inventive Example 1 except that Ti was replaced with Hf as the auxiliary catalyst and the constituents were mixed at ratios of Ni:Y:Hf:C=2:2:1:95 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 1.

Inventive Example 4:

Carbon nanotubes were manufactured in the same manner as with Inventive Example 1 except that Ti was replaced with Nb as the auxiliary catalyst and the constituents were mixed at ratios of Ni:Y:Nb:C=2:2:1:95 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 1.

Inventive Example 5:

Carbon nanotubes were manufactured in the same manner as with Inventive Example 1 except that Ti was replaced with B as the auxiliary catalyst and the constituents were mixed at ratios of Ni:Y:B:C=2:2:2:94 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 1.

Inventive Example 6:

Carbon nanotubes were manufactured in the same manner as with Inventive Example 1 except that Ti was replaced with Si as the auxiliary catalyst and the constituents were mixed at ratios of Ni:Y:Si:C=2:2:1:95 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 1.

Comparative Example 1:

Carbon nanotubes were manufactured in the same manner as with Inventive Example 1 except that the mixed catalyst was a mixture of powders of Ni and Y and a powder of graphite and the constituents were mixed at ratios of Ni:Y:C=3:3:94 (atom number ratios) with respect to the total amount of the positive electrode.

Then, the web (web A) shaped like a spider web and the web (web B), other than the web shaped like a spider web, attached to the inner wall of the arc discharging chamber 2 were weighed in the exactly same manner as with Inventive Example 1. The web A had a weight of 1.1 g, and the web B had a weight of 1.8 g. The total yield amount of the retrieved webs was therefore 2.9 g.

Then, the consumed amount of the positive electrode and the total yield percentage of the retrieved webs were calculated and the G/D ratio of the web A was measured in the same manner as with Inventive Example 1. The consumed amount of the positive electrode was 13.5 g, and the total yield percentage of the retrieved webs was 21.5%. The consumed amount of the positive electrode, the total yield amount of the retrieved webs, the total yield percentage of the retrieved webs, and the G/D ratio are shown in Table 1.

TABLE 1

| | | | Consumed | | | |
|---|---|---|---|---|---|---|
| | | | amount | Total | Total | |
| | | Auxil- | of elec- | yield | yield | |
| | Main | iary | trode | amount | percent- | G/D ra- |
| | catalyst | catalyst | (g) | (g) | age (%) | tio |
| Inven- | Ni, Y | Ti | 7.3 | 2.5 | 34.2 | 5.13 |
| tive Ex- | | | | | | |
| ample 1 | | | | | | |
| Inven- | Ni, Y | Zr | 6.9 | 1.9 | 27.5 | 3.90 |
| tive Ex- | | | | | | |
| ample 2 | | | | | | |
| Inven- | Ni, Y | Hf | 7.1 | 2.1 | 29.6 | 3.79 |
| tive Ex- | | | | | | |
| ample 3 | | | | | | |
| Inven- | Ni, Y | Nb | 6.6 | 1.8 | 27.3 | 3.88 |
| tive Ex- | | | | | | |
| ample 4 | | | | | | |
| Inven- | Ni, Y | B | 7.1 | 2.0 | 28.2 | 2.95 |
| tive Ex- | | | | | | |
| ample 5 | | | | | | |
| Inven- | Ni, Y | Si | 6.8 | 1.8 | 26.5 | 2.81 |
| tive Ex- | | | | | | |
| ample 6 | | | | | | |
| Compara- | Ni, Y | — | 13.5 | 2.9 | 21.5 | 2.19 |
| tive Ex- | | | | | | |
| ample 1 | | | | | | |

It is clear from Table 1 that Inventive Examples 1 through 6 which use catalysts including Ni—Y as a main catalyst and either one of Ti, Zr, Hf, Nb, B, and Si as an auxiliary catalyst have total yield percentages of webs much greater than Comparative Example 1 which uses only Ni—Y as a catalyst, and that Inventive Examples 1 through 6 have G/D ratios higher than Comparative Example 1, producing more carbon nanotubes contained in the webs.

Inventive Example 7:

Carbon nanotubes were manufactured in the same manner as with Inventive Example 1 except that Y was replaced with Fe as the main catalyst and the constituents were mixed at ratios of Ni:Fe:Zr:C=2:2:2:94 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 2.

Comparative Example 2:

Carbon nanotubes were manufactured in the same manner as with Inventive Example 1 except that the mixed catalyst was a mixture of powders of Ni and Fe and a powder of graphite and the constituents were mixed at ratios of Ni:Fe:C=2:2:96 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 2.

TABLE 2

| | | | Consumed | | | |
|---|---|---|---|---|---|---|
| | | | amount | Total | Total | |
| | | Auxil- | of elec- | yield | yield | |
| | Main | iary | trode | amount | percent- | G/D ra- |
| | catalyst | catalyst | (g) | (g) | age (%) | tio |
| Inven- | Ni, Fe | Ti | 7.0 | 1.8 | 25.7 | 3.10 |
| tive Ex- | | | | | | |
| ample 7 | | | | | | |
| Compara- | Ni, Fe | — | 12.8 | 2.9 | 22.7 | 1.97 |
| tive Ex- | | | | | | |
| ample 2 | | | | | | |

It is clear from Table 2 that Inventive Example 7 which uses catalysts including Ni—Fe as a main catalyst and Ti as an auxiliary catalyst has a total yield percentage of webs much greater than Comparative Example 2 which uses only Ni—Fe as a catalyst, and that Inventive Example 7 has a G/D ratio higher than Comparative Example 2, producing more carbon nanotubes contained in the webs.

Inventive Example 8:

Carbon nanotubes were manufactured in the same manner as with Inventive Example 1 except that Ni, Y were replaced with Co alone as the main catalyst and the constituents were mixed at ratios of Co:Ti:C=2:0.5:97.5 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 3.

Inventive Example 9:

Carbon nanotubes were manufactured in the same manner as with Inventive Example 8 except that Ti was replaced with Cr as the main catalyst and the constituents were mixed at ratios of Co:Cr:C=2:2:96 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 3.

Comparative Example 3:

Carbon nanotubes were manufactured in the same manner as with Inventive Example 1 except that the mixed catalyst was replaced with a mixture of a powder of Co and a powder of graphite and the constituents were mixed at ratios of Co:C=2:98 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 3.

TABLE 3

| | | | Consumed | | | |
|---|---|---|---|---|---|---|
| | | | amount | Total | Total | |
| | | Auxil- | of elec- | yield | yield | |
| | Main | iary | trode | amount | percent- | G/D ra- |
| | catalyst | catalyst | (g) | (g) | age (%) | tio |
| Inven- | Co | Ti | 6.9 | 2.0 | 29.0 | 4.12 |
| tive Ex- | | | | | | |
| ample 8 | | | | | | |
| Inven- | Co | Cr | 6.6 | 1.8 | 27.3 | 3.77 |
| tive Ex- | | | | | | |
| ample 9 | | | | | | |
| Compara- | Co | — | 4.5 | 0.5 | 11.1 | 2.11 |
| tive Ex- | | | | | | |
| ample 3 | | | | | | |

It is clear from Table 3 that Inventive Examples 8, 9 which use catalysts including Co as a main catalyst and Ti or Cr as an auxiliary catalyst have total yield percentages of webs much greater than Comparative Example 3 which uses only Co as a catalyst, and that Inventive Examples 8, 9 have G/D ratios higher than Comparative Example 3, producing more carbon nanotubes contained in the webs.

Inventive Example 10:

Carbon nanotubes were manufactured in the same manner as with Inventive Example 1 except that Y was replaced with La as the main catalyst and the constituents were mixed at ratios of Ni:La:Ti:C=2:2:2:94 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 4.

Inventive Example 11:

Carbon nanotubes were manufactured in the same manner as with Inventive Example 1 except that Ni, Y were replaced with Rh, La as the main catalyst and the constituents were mixed at ratios of Rh:La:Ti:C=1:1:2:96 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 4.

Inventive Example 12:

Carbon nanotubes were manufactured in the same manner as with Inventive Example 1 except that Ni, Y were replaced with Rh as the main catalyst and the constituents were mixed at ratios of Rh:Ti:C=1.5:2:96.5 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 4.

Inventive Example 13:

Carbon nanotubes were manufactured in the same manner as with Inventive Example 1 except that Ni, Y were replaced with La alone as the main catalyst and the constituents were mixed at ratios of La:Ti:C=2:2:96 (atom number ratios) with respect to the total amount of the positive electrode.

The consumed amount of the positive electrode and the total yield percentage of the retrieved webs were calculated and the G/D ratio of the web A was measured in the same manner as with Inventive Example 1. The results are shown in Table 4.

TABLE 4

| | | | Consumed | | | |
|---|---|---|---|---|---|---|
| | | | amount | Total | Total | |
| | | Auxil- | of elec- | yield | yield | |
| | Main | iary | trode | amount | percent- | G/D ra- |
| | catalyst | catalyst | (g) | (g) | age (%) | tio |
| Inven- | Ni, La | Ti | 6.6 | 1.8 | 27.3 | 3.97 |
| tive Ex- | | | | | | |
| ample 10 | | | | | | |
| Inven- | Rh, La | Ti | 6.2 | 1.8 | 29.0 | 2.78 |
| tive Ex- | | | | | | |
| ample 11 | | | | | | |
| Inven- | Rh | Ti | 5.2 | 1.5 | 28.8 | 3.11 |
| tive Ex- | | | | | | |
| ample 12 | | | | | | |
| Inven- | La | Ti | 5.2 | 1.6 | 30.8 | 2.67 |
| tive Ex- | | | | | | |
| ample 13 | | | | | | |

It is clear from Table 4 that Inventive Examples 10 through 13 which use catalysts including one or two metals of Ni, Rh, La as a main catalyst and Ti as an auxiliary catalyst have total yield percentages of webs and G/D ratios which are equivalent to those of Inventive Examples 1 through 9.

In the above Inventive Examples, nothing is disclosed about a main catalyst including at least one metal of Ru, Pd, Pt, Ce. However, Ru, Pd, Pt, Ce are considered to offer the same effect as Rh which is a platinum element of the same group. Ce is considered to offer the same effect as Y, La which are rare earth elements of the same group.

In the above Inventive Examples, nothing is disclosed about an auxiliary catalyst including at least one metal of V, Ta, Mo, W, Al. However, V, Ta are considered to offer the same effect as Nb which is a VA-group element of the same group. Mo, W are considered to offer the same effect as Cr which is a VIA-group element of the same group. Al is considered to offer the same effect as B which is a IIIB-group element of the same group.

Although a certain preferred embodiment of the present invention has been shown and described in detail, it should be understood that various changes and modifications may be made therein without departing from the scope of the appended claims.

What is claimed is:

1. A method of manufacturing a carbon nanotube, comprising the step of generating a web including a carbon nanotube by causing a high-energy heat source to act on carbon in the presence of catalysts, said catalysts including a main catalyst made of at least one metal which is selected from the group consisting of an iron group element, a platinum group element, and a rare earth element, is substantially a pure material or an alloy, and may contain unavoidable impurities, and an auxiliary catalyst made of a material which causes an exothermic reaction in a process of generating the web including the carbon nanotube.

2. A method according to claim 1, wherein said auxiliary catalyst is made of a material for generating a carbide more stable in terms of thermal energy than a carbide generated by said main catalyst in the process of generating the web including the carbon nanotube.

3. A method according to claim 2, wherein said auxiliary catalyst is made of such a material that the free formation energy of the carbide generated therefrom is smaller than the free formation energy of the carbide generated by said main catalyst.

4. A method according to claim 1, wherein said main catalyst is made of at least one metal which is selected from the group consisting of Fe, Co, Ni, Rh, Ru, Pd, Pt, Y, La, and Ce, is substantially a pure material or an alloy, and may contain unavoidable impurities, and said auxiliary catalyst is made of at least one material selected from the group consisting of Ti, Zr, Hf, V, Nb, Ta, Cr, Mo, W, B, Al, and Si, is substantially a pure material or an alloy, and may contain unavoidable impurities.

5. A method according to claim 4, wherein said main catalyst is made of a mixture of Ni and Y, each of which is substantially a pure material or an alloy and may contain unavoidable impurities, and said auxiliary catalyst is made of at least one material selected from the group consisting of Ti, Zr, Hf, Nb, B, and Si, is substantially a pure material or an alloy, and may contain unavoidable impurities.

6. A method according to claim 5, wherein said main catalyst is made of a mixture of Ni and Y, each of which is substantially a pure material or an alloy and may contain unavoidable impurities, and said auxiliary catalyst is made of Ti, which is substantially a pure material and may contain unavoidable impurities.

7. A method according to claim 4, wherein said main catalyst is made of a mixture of Ni and Fe, each of which is substantially a pure material or an alloy and may contain unavoidable impurities, and said auxiliary catalyst is made of Ti, which is substantially a pure material and may contain unavoidable impurities.

8. A method according to claim 4, wherein said main catalyst is made of Co, which is substantially a pure material or an alloy and may contain unavoidable impurities, and said auxiliary catalyst is made of one of Ti and Cr, each of which is substantially a pure material and may contain unavoidable impurities.

9. A method according to claim 4, wherein said main catalyst is made of at least one material which is selected from the group consisting of Ni, La, and Rh, is substantially a pure material or an alloy, and may contain unavoidable impurities, and said auxiliary catalyst is made of Ti, which is substantially a pure material and may contain unavoidable impurities.

10. A method according to claim 1, wherein said carbon serves as carbon electrodes, and said high-energy heat source comprises an arc discharge caused between said carbon electrodes.

11. A method according to claim 10, wherein said carbon electrodes contain a total amount of the main and auxiliary catalysts which is in the range from 10 to 35 weight % with respect to the total amount of the carbon electrodes.

12. A method according to claim 1, wherein said auxiliary catalyst is mixed in an amount in excess of 0.1 atomic % of the total amount of the main and auxiliary catalysts.
